(19) United States
(12) Patent Application Publication
(10) Pub. No.: US 2008/0139436 A1
(43) Pub. Date: Jun. 12, 2008

(54) Two step cleaning process to remove resist, etch residue, and copper oxide from substrates having copper and low-K dielectric material

(76) Inventor: Chris Reid, Hamilton (GB)

Correspondence Address: MORGAN LEWIS & BOCKIUS LLP, 1111 PENNSYLVANIA AVENUE NW, WASHINGTON, DC, 20004, US

(21) Appl. No.: 11/898,990

(22) Filed: Sep. 18, 2007

Related U.S. Application Data
(60) Provisional application No. 60/845,259, filed on Sep. 18, 2006.

(51) Int. Cl. C11D 3/26; G03F 7/42; C11D 3/24

(52) U.S. Cl. 510/176; 510/175

(57) ABSTRACT

A method for two step cleaning of semiconductor substrate wherein a first formulation is contacted with the substrate and subsequently a second formulation is contacted with the substrate, optionally followed with a deionized water wash. The first formulation may be remover compositions referred to in the specification, such as a fluoride containing composition, and the second formulation may comprise a basic compound and from 0% to about 90% water, and may further comprise water from 0% to about 92.5% organic solvent.

### RELATED APPLICATION

This application claims priority from U.S. Provisional Patent Application Ser. No. 60/845,259 filed on Sep. 18, 2006, incorporated herein by reference.

### FIELD OF THE INVENTION

The present invention generally relates to compositions and methods for cleaning integrated circuit substrates. The invention more particularly relates to two step methods for removal of photoresist, post etch residue, and/or post planarization residue from substrates comprising copper, where one of the compositions comprises a basic compound.

### BACKGROUND OF THE INVENTION

Devices with critical dimensions on the order of 90 nanometers have involved integration of copper conductors and low-k dielectrics. Devices with critical dimensions on the order of 90 nanometers require alternating material deposition processes and planarization processes. Following almost each step in the fabrication process, e.g., a planarization step, a trenching step, or an etching step, cleaning processes are required to remove residues of the plasma etch, oxidizer, abrasive, metal or other liquids or particles remaining which contaminate the surface of the wafer. Prior art devices were fabricated from aluminum and/or tungsten conductors with silica dielectrics. Fabrication of the current advanced generation of devices require copper conductors and low-k dielectric materials (typically carbon-silica or porous silica materials), both of which can react with and be damaged by various classes of prior art cleaners.

Low-k dielectrics in particular may be damaged in the cleaning process as evidenced by etching, changes in porosity/size, and ultimately changes in dielectric properties. Time required to remove residues depends on the nature of the residue, the process (heating, crosslinking, etching, baking, and/or ashing) by which it is created, and whether batch or single wafer cleaning processes are used. Some residues may be cleaned in a very short period of time, while some residues require much longer cleaning processes. Compatibility with both the low-k dielectric and with the conductor over the duration of contact with the cleaner is a desired characteristic.

Devices with critical dimensions on the order of 65 nanometers or smaller may use a metal hard mask when etching low-k dielectric materials. Titanium nitride is one such metal that may be used. The residues of the plasma etch contain components of the metal hard mask and are particularly difficult to remove using currently available compositions and methods.

Cleaning processes fall into two broad process classes: batch and single wafer. Batch cleaning typically involves multiple wafers, and the cleaning process occurs on the order of minutes, usually by contacting the wafers with an agitated cleaning solution at a temperature between about 20° C. and about 100° C., typically between 30° C. and 75° C., for a period of time ranging from 3 minutes to about 60 minutes, typically between 10 to 30 minutes. In a batch mode, the plurality of wafers are typically immersed in the cleaning solution or exposed to a constant spray of cleaning solution. The single wafer cleaning process involves cleaning under more rigid conditions of agitation and contact, at temperatures similar to or up to about 20° C. higher than comparable immersion process temperatures, but for a period of time that ranges from about 5 seconds but less than 3 minutes, and typically between 30 to 90 seconds, as the composition is dispensed onto a spinning wafer.

Most often a cleaning method includes applying the cleaning formulation and subsequently rinsing the substrate with purified water. If the cleaning formulation is not miscible with water an intermediate rinse with isopropanol or isopropanol/water mixers is used with subsequent rinse with purified water.

Two step cleaning methods are known. For example commonly assigned U.S. Pat. No. 5,981,454 describes a composition containing a monofunctional, difunctional or trifunctional organic acid and a buffering amount of a quaternary amine, ammonium hydroxide, hydroxylamine, hydroxylamine salt, hydrazine or hydrazine salt base with pH between about 3.5 and about 7. The composition is described as useful in combination with formulations which are hydroxylamine-base, amine-based or alkanloamine-based.

Acidic cleaning formulations are known as well.

Commonly owned US Patent Publication No. US 2006-0199749 describes formulations comprising: (a) a fluoride-providing component; (b) at least 1.5% by weight of a water miscible glycol ether, amide, sulfoxide, or mixture thereof; (c) an acid; (d) at least about 80% by weight water; and (e) optionally a chelator. The pH of these formulations is typically acidic, but may also be slightly basic.

Commonly owned US Patent Publication No. 2005-0245409 describes formulations comprising (a) H₂SiF₆, HBF₄, or both; (b) an organic solvent; (c) optionally an amine; (d) a corrosion inhibitor; and (e) water, or in another embodiment a composition including: H₂SiF₆, water, and optionally a corrosion inhibitor. In preferred embodiments, the composition has H₂SiF₆, and the pH lower than 7.

Commonly owned US Patent Publication No. 2004-0137736 describes dilute aqueous solutions containing phosphoric acid and methods for cleaning plasma etch residue from semiconductor substrates including such dilute aqueous solutions.

However, it has been found that in some applications, the use of a cleaning formulation alone, such as a formulation containing a fluoride-containing component, is not always sufficient to achieve the level of residue removal desired in present semiconductor processes. It has further been found that the subsequent use of traditional subsequent treatment chemistries, such as isopropyl alcohol, is not always sufficient to achieve the desired level of residue removal. In light of the demands in such semiconductor processes, it is clear that it would be highly desirable to provide formulations that are useful in a two step cleaning procedures that provide more effective residue removal. The present invention addresses this need and provides formulations that provide more effective removal.

### DESCRIPTION OF EMBODIMENTS

Reference will now be made in detail to various embodiments, examples of which are illustrated in the examples set forth herein. In the following detailed description, numerous specific details are set forth in order to provide a thorough understanding of the subject matter presented herein. It will be apparent to one of ordinary skill in the art that the subject matter may be practiced without these specific details. In other instances, well-known methods, procedures, and components have not been described in detail so as not to unnecessarily obscure aspects of the embodiments.

### SUMMARY OF THE PREFERRED EMBODIMENTS

Formulations useful in a two step cleaning method comprising two or more formulations, wherein a substrate is contacted with a first formulation, herein referred to as the cleaning formulation, followed by contacting the substrate with a second formulation, herein referred to as the rinse formulation, wherein the rinse formulation comprises: (a) about 5% to about 50% by weight of a basic compound; (b) 0 to about 90% by weight water; and (c) 0 to about 92.5% by weight organic solvent.

In another embodiment, the rinse formulation comprising (a) about 5% to about 50% by weight of a basic compound; (b) 0 to about 90% by weight water; and (c) 0 to about 92.5% by weight organic solvent contacts a substrate before the cleaning formulation contacting the substrate.

In a preferred embodiment, the cleaning formulation is a fluorine-containing cleaning formulation.

Another embodiment of the present invention is a two-step cleaning process for cleaning a semiconductor substrate comprising the steps of: (1) contacting the substrate with a first formulation (cleaning formulation); (2) contacting the substrate with deionized water; and (3) contacting the substrate with a second formulation (rinse formulation) comprising a basic compound, 0-about 90% by weight water, 0-92.5% by weight organic solvent.

In one embodiment, the substrate is immersed in the cleaning formulation and spray rinsed with the rinse formulation. In another embodiment, the substrate is separately immersed in both the cleaning formulation and the rinse formulation. In another embodiment, the substrate is separately sprayed with both the cleaning formulation and the rinse formulation. In other embodiments the substrate is contacted with the formulations as designed for the process.

### DETAILED DESCRIPTION OF THE PREFERRED EMBODIMENTS

This document uses the following abbreviations.

BHEMA—Bis(hydroxyethyl) dimethyl ammonium hydroxide

Choline—Hydroxyethyl trimethyl ammonium hydroxide, 45% solution in water

DEHA—N,N-Diethylhydroxylamine, 80% solution in water

DIW—Deionized water

DMSO—Dimethyl sulfoxide

DPGME—Dipropylene glycol methyl ether

HAFB—Hydroxylamine free base, 50% solution in water

HF—Hydrogen fluoride

IPA—Isopropyl alcohol

Low-k dielectric—a dielectric material with dielectric constant less than about 2.5 MDEA—Methyl diethanolamine

NMP—N-methylpyrrolidinone

s—Seconds

THEMAH—Tris(hydroxyethyl) methyl ammonium hydroxide, 49% solution in water

TiN—Titanium Nitride

A process of the invention includes a two step process for cleaning a semiconductor substrate comprising the steps of: (1) contacting the substrate with a first formulation (cleaning formulation) and (2) contacting the substrate with a second formulation comprising a basic compound, 0-about 90% by weight water, 0-92.5% by weight organic solvent (rinse formulation).

Typically the substrate is a semiconductor wafer. In one embodiment the substrate comprises copper and low-k dielectric layers. In another embodiment the substrate comprises a titanium nitride layer hard mask over a low-k dielectric layer.

Having been subjected to a processing step such as an etch step, the substrate will contain residues that must be removed before further processing may be performed.

The cleaning process includes two steps to completely remove the etch residue. A first step includes applying a composition as is known in the art such as one described in the following three published patents, US 2006-0199749, 2005-0245409, and 2004-0137736. This formulation is referred to herein as the cleaning formulation.

Commonly owned US Patent Publication No. US 2006-0199749 describes formulations comprising: (a) a fluoride-providing component; (b) at least 1.5% by weight of a water miscible glycol ether, amide, sulfoxide, or mixture thereof; (c) an acid; (d) at least about 80% by weight water; and (e) optionally a chelator. The pH of these formulations is typically acidic, but may also be slightly basic. U.S. Patent Publication No. US 2006-0199749 comprise remover formulations that can effectively be used in the present invention. Such publication is hereby incorporated by reference as if detailed here in its entirety. Another example of such a composition comprises a) a fluoride-providing component providing between about 0.01% and 0.2% by weight fluoride; b) between about 1% and about 12.5% by weight of a glycol ether; c) between about 0.2% and about 2% of an organic acid; and d) between about 85% and about 98.79% by weight water.

The fluoride-providing component must provide fluoride ions, and may be selected from the group consisting of fluoride-containing acids and/or metal-free salts thereof. The term “metal-free salt of fluoride-containing acid” as used herein means metals are not contained in the salt anion or cation. The salt may be formed by combining a fluoride-containing acid such as hydrogen fluoride, tetrafluoroboric acid, and/or trifluoroacetic acid, with any of ammonium hydroxide; a C₁-C₄ alkyl quaternary ammonium ions such as tetramethylammonium, tetraethylammonium and trimethyl(2-hydroxyethyl)ammonium; or a primary, secondary or tertiary amines such as monoethanolamine, 2-(2-aminoethylamino)ethanol, diethanolamine, 2-ethylaminoethanol and dimethylaminoethanol.

Exemplary fluoride-containing components include hydrogen fluoride and/or its salts ammonium fluoride and/or ammonium bifluoride (ammonium hydrogen difluoride); fluoroboric or tetrafluoroboric acid and/or its salts such as ammonium tetrafluoroborate; fluoroacetic or trifluoroacetic acid and/or its salts such as ammonium trifluoroacetate; fluorosilicic acid and/or its salts, and any mixtures thereof. As used herein, fluorine and fluoride are used interchangeably. Preferred fluorine-containing components include hydrogen fluoride, ammonium fluoride, ammonium bifluoride, alkylammonium fluoride, alkylammonium bifluoride, and mixtures thereof, where the alkylammonium fluoride and/or bifluoride comprises 1 to 8 carbon atoms, preferably from 1-4 carbon atoms, and is a mono-, di-, tri-, or tetra-alkylammonium group. More preferably, the fluoride-providing compound consists essentially of ammonium fluoride, ammonium bifluoride, or both, most preferably ammonium fluoride.

Exemplary glycol ether species useful in the compositions are the same as described herein. Other solvents include but are not limited to sulfoxides, sulfones, amides, lactams, and lactones, or combinations thereof, as described herein.

Organic acid species useful in the composition include but are not limited to formic acid, acetic acid, propanoic acid, butyric acid and the like; hydroxy substituted carboxylic acids including but not limited to glycolic acid, lactic acid, tartaric acid and the like; oxalic acid; carbonyl substituted carboxylic acids including but not limited to glyoxylic acid, and the like; amino substituted carboxylic acids including but not limited to glycine, hydroxyethylglycine, cysteine, alanine and the like; cyclic carboxylic acids including but not limited to ascorbic acid and the like; oxalic acid, nitrilotriacetic acid, citric acid, and mixtures thereof.

Commonly owned US Patent Publication No. 2005-0245409 describes formulations comprising (a) H₂SiF₆, HBF₄, or both; (b) an organic solvent; (c) optionally an amine; (d) a corrosion inhibitor; and (e) water, or in another embodiment a composition including: H₂SiF₆, water, and optionally a corrosion inhibitor. In preferred embodiments, the composition has H₂SiF₆, and the pH lower than 7. The formulations of U.S. Patent Publication No. US 2005-0245409 comprise remover formulations that can effectively be used in the present invention. Such publication is hereby incorporated by reference as if detailed here in its entirety.

Examples of remover formulations of US 2005-0245409 include: (a) H₂SiF₆ at a concentration from about 0.001% to about 5% by weight of the composition; (b) the organic solvent at a concentration from about 50% to about 98% by weight of the composition; (c) the amine at a concentration less than about 1.5% by weight of the composition; (d) the corrosion inhibitor at a concentration from about 0.001% to about 10% by weight of the composition; and (e) balance of water; and (a) HBF₄ at a concentration from about 0.001% to about 5% by weight of the composition; (b) the organic solvent at a concentration from about 50% to about 98% by weight of the composition; (c) the amine at a concentration less than about 1.5% by weight of the composition; (d) the corrosion inhibitor at a concentration from about 0.001% to about 10% by weight of the composition; and (e) balance of water.

Examples of such organic solvents include, but are not limited to: amides such as N,N-dimethylformamide, N,N-dimethylacetaamide, N,N-diethylformamide, N,N-diethylacetamide, N-methylformamide, and N-methylacetamide; pyrrolidones such as N-methyl-2-pyrrolidone, N-ethyl-2-pyrrolidone, and N-hydroxyethyl-2-pyrrolidone; imidazolidinones such as 1,3-dimethyl-2-imidazolidinone, and 1-3-diethyl-2-imidazolidinone; alkyl ureas such as tetramethyl urea, and tetraethyl urea; polyhydric alcohols and their derivatives such as ethylene glycol, ethylene glycol mono-methyl ether, ethylene glycol mono-ethyl ether, ethylene glycol mono-butyl ether, ethylene glycol mono-methyl ether acetate, ethylene glycol mono-ethyl ether acetate, diethylene glycol, diethylene glycol mono-methyl ether, diethylene glycol mono-ethyl ether, diethylene glycol mono-propyl ether, diethylene glycol mono-butyl ether, triethylene glycol mono-methyl ether, propylene glycol, propylene glycol mono-methyl ether, propylene glycol mono-ethyl ether, propylene glycol mono-butyl ether, dipropylene glycol mono-methyl ether, dipropylene glycol mono-ethyl ether, dipropylene glycol mono-propyl ether, dipropylene glycol mono-butyl ether, diethylene glycol dimethyl ether, diethylene glycol diethyl ether, diethylene glycol dipropyl ether, diethylene glycol diethyl ether, diethylene glycol dipropyl ether, diethyl glycol dibutyl ether, and triethylene glycol dimethyl ether; sulfoxides such as dimethyl sulfoxide, and diethyl sulfoxide; lactones such as .gamma.-butyrolactone, and sigma.-valerolactone; oxycarbonic acid derivatives such as methyl lactate, ethyl lactate, propyl lactate, and butyl lactate; oxazolidinones such as 3-methyl-2-oxazolidinone and 3-ethyl-2-oxaxolidinone; and the like; and combinations thereof. Preferred organic solvents include an amide, an ether, or mixture thereof. The most preferred organic solvent is an amide, e.g., an N-alkyl-2-pyrrolidone.

Examples of such amines can include, but are not limited to: alkanolamines such as mono-, di-, and tri-isopropanolamine, 2-(2-aminoethylamino)-ethanol, 2-(2-aminoethoxy)-ethanol (“DGA”), 2-aminoethanol (“monoethanolamine” or “MEA”), 2-(N-methylamino) ethanol (“monomethyl ethanolamine” or “NMEA”), 2-amino-1-propanol (“monoisopropanolamine” or “MIPA”), 2-(N-hydroxyethyl-amino)-ethanol (“diethanolamine” or “DEA”), 2-[(2-aminoethyl)-(2-hydroxyethyl)-amino]-et-hanol (“N,N-bis-hydroxyethyl-ethylenediamine”), N,N,N-tris-(2-hydroxyethyl-)-ammonia (“triethanolamine” or “TEA”), N-aminoethyl-N′-hydroxyethyl-ethyl-enediamine, N,N′-dihydroxyethyl-ethylenediamine, 2-[2-(2-aminoethoxy)-ethyl-lamino]-ethanol, 2-[2-(2-aminoethylamino)-ethoxy]-ethanol, 2-[2-(2-aminoethoxy)-ethoxy]-ethanol, tertiarybutyldiethanolamine, isopropanolamine, diisopropanolamine, 3-amino-1-propanol (“n-propanolamine” or “NPA”), isobutanolamine, 2-(2-aminoethoxy)-propanol-, and the like, and combinations thereof; other alcohol-amines such as hydroxyaniline (e.g., 1-hydroxy-2-aminobenzene), hydroxylamine, hydroxylamine derivatives; and the like; and combinations thereof.

Examples of corrosion inhibitors include, but are not limited to: nitrate salts of ammonium; hydrocarbon-substituted ammonium nitrate salts; benzotriazole; 2,4-pentandione dioxime; 1,6-dioxaspiro[4,4]nonane 2,7-dione (di-ether); thiourea; ammonium bisulfite; choline salts, e.g., bisulfite, nitrate, hydroxide, or the like, or a combination thereof; bischoline salts, e.g., bisulfite, nitrate, hydroxide, or the like, or a combination thereof; trischoline salts, e.g., bisulfite, nitrate, hydroxide, or the like, or a combination thereof; glycerol; sorbitol; gelatine; starch; phosphoric acid; silicic acid; polyethylene oxide; polyethylene imine; benzotriazole; gallic acid or gallic acid esters; glycolic acid or glycolic acid esters; sugar alcohols such as traitol, erythritol, adonitol, xylitol, teritol, idetol, and dulcitol; and the like; and combinations thereof.

Commonly owned US Patent Publication No. 2004-0137736 describes dilute aqueous solutions containing phosphoric acid and methods for cleaning plasma etch residue from semiconductor substrates including such dilute aqueous solutions. The formulations of U.S. Patent Publication No. US 2004-0013773 comprise remover formulations that can effectively be used in the present invention. Such publication is hereby incorporated by reference as if detailed herein its entirety. A dilute aqueous cleaner and residue remover comprising: water, optionally in a mixture with one or more polar organic solvents, wherein the water is present at least about 75% by weight; phosphoric acid or salt thereof, present in an amount from about 0.1% to about 6% by weight of 85% phosphoric acid; optionally, an alkaline component, such as quaternary ammonium compound, present in the solution in an amount from about 0.2% to about 5% by weight; optionally, a hydroxylamine derivative, present in the solution in an amount from about 0.1% to about 5% by weight not including the counterion of the hydroxylamine derivative salt, if present; optionally, an alkanolamine, present in the solution in an amount from about 0.2% to about 5% by weight; optionally, a fluoride-containing or fluoride-providing compound, present in the solution in an amount from about 0.001% to about 0.5% by weight; optionally, an other acid compound, present in the solution in an amount from about 0.05% to about 6% by weight; optionally, a chelating agent, present in the solution in an amount from about 0.1% to about 8% by weight; optionally, a surfactant, present in the solution in an amount from about 0.01% to about 3% by weight.

Exemplary quaternary ammonium compounds include, but are not limited to, ammonium hydroxide; alkylammonium compounds such as monoalkylammonium hydroxide, dialkylammonium hydroxide, trialkylammonium hydroxide, and/or tetraalkylammonium hydroxides (e.g., tetramethylammonium hydroxide, choline hydroxide, di(2-hydroxyethyl)dimethylammonium hydroxide, tris(2-hydroxyethyl)methylammonium hydroxide, and the like, and mixtures thereof); and mixtures thereof. While the hydroxide counterion is preferred for these quaternary ammonium compounds, other alternate counterions are also contemplated, including, but not limited to, bisulfite, sulfite, sulfate, nitrate, nitrite, phosphate, phosphite, carbonate, trifluoroacetate, organic carboxylates from organic acids such as those listed herein, and the like, and combinations thereof. Compounds containing two or more ammonium moieties are also useful, both as a cleaning additive and as a chelating agent.

Examples of derivatives of hydroxylamine according to the invention include, but are in no way limited to, hydroxylamine; alkylhydroxylamines such as N-methyl-hydroxylamine, N,N-dimethyl-hydroxylamine, N-ethyl-hydroxylamine, N,N-diethyl-hydroxylamine, methoxylamine, ethoxylamine, N-methyl-methoxylamine, N-isopropylhydroxylamine, and the like, and mixtures thereof.

Exemplary alkanolamines include, but are not limited to, monoethanolamine, 2-(2-hydroxylethylamino)ethanol (i.e., diethanolamine or DEA), 2-(2-aminoethoxy)ethanol (i.e., diglycolamine or DGA), N,N,N-tris(2-hydroxyethyl)-ammonia (i.e., triethanolamine or TEA), isopropanolamine, 3-amino-1-propanol (i.e., n-propanolamine or NPA), 2-amino-1-propanol (“monoisopropanolamine” or “MIPA”), 2-(N-methylamino)ethanol (i.e., monomethylethanolamine or MMEA), 2-(2-aminoethylamino)ethanol (i.e., aminoethylaminoethanol or AEEA), and mixtures thereof.

Examples of chelating agents include, but in no way limited to, mono-, di-, or multi-hydroxybenzene-type compounds, e.g., such as catechol, resorcinol, butylated hydroxytoluene (“BHT”), and the like, or a combination thereof. In one embodiment the chelators include three or more carboxylic acid-containing moieties, e.g., such as ethylenediamine tetraacetic acid (“EDTA”), non-metallic EDTA salts, and the like, or a combination thereof. Compounds containing a two carboxylic acid moieties are less preferred. Compounds containing both hydroxyl and carboxylic acid moieties are useful in one embodiment. Aromatic compounds containing thiol groups, e.g., such as thiophenol; amino-carboxylic acids; diamines, e.g., such as ethylene diamine; polyalcohols; polyethylene oxide; polyamines; polyimines; or a combination thereof, are useful in one embodiment. In one embodiment, one or more chelating agents can be used in one composition, where the chelating agents are selected from groups described above. Alternately or additionally, some chelating agents are described in U.S. Pat. No. 5,417,877, issued May 23, 1995 to Ward, and in commonly assigned U.S. Pat. No. 5,672,577, issued Sep. 30, 1997 to Lee, the disclosures of each of which are incorporated herein by reference. In an alternate embodiment, the composition is substantially free from chelating agents.

Preferred compositions of the first step include a fluoride-containing or fluoride providing compound such as hydrogen fluoride and a salt of hydrogen fluoride such as ammonium fluoride or ammonium bifluoride. Ammonium fluoride and ammonium bifluoride are particularly preferred.

One particularly preferred ammonium fluoride composition is S2X9 which consists of 0.1% ammonium fluoride (40% aqueous); 2.5% propylene glycol monomethyl ether; 2.5% glyoxylic acid monohydrate; 0.06% 1-Hydroxyethylidene-1,1-diphosphonic acid; and balance water.

A second step includes applying a composition comprising a basic compound, 0 to about 90% by weight water, 0 to about 92.5% by weight organic solvent.

### Basic Compound

The basic compound may be an organic ammonium compound; an oxoammonium compound; or an alkanolamine. It is preferable for the second-step composition (rinse formulation) to contain from about 5 to about 50% by weight of the basic compound. In another embodiment it is preferable for the rinse formulation to contain from about 7.5 to about 30% by weight of the basic compound. In another embodiment it is preferable for the rinse formulation to contain from about 10 to about 25% by weight of the basic compound.

Organic ammonium compounds that may be useful have the formula

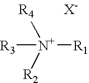

wherein: X is hydroxide, sulfate, hydrogen sulfate, phosphate, hydrogen phosphate, dihydrogen phosphate, nitrate, a carboxylate, a halide, carbonate, hydrogen carbonate, bifluoride, or a combination thereof, R₁ is an alkyl group or a group derived from the reaction of a tertiary amine with an organic epoxy, and R₂, R₃, and R₄ are each not hydrogen and are independently alkyl, benzyl, hydroxyalkyl, phenyl, a group derived from the reaction of a tertiary amine with an organic epoxy, or another group contained in a tertiary amine. Exemplary ammonium compounds include tetramethylammonium hydroxide; choline; THEMAH; and BHEMAH.

Oxoammonium compounds that may be useful in have the formula

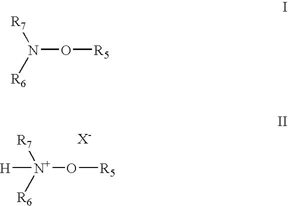

wherein: X is hydroxide, sulfate, hydrogen sulfate, phosphate, hydrogen phosphate, dihydrogen phosphate, nitrate, a carboxylate, a halide, carbonate, hydrogen carbonate, bifluoride, or a combination thereof, each R₅ is independently hydrogen, a substituted C₁-C₆ straight, branched, or cyclic alkyl, alkenyl, or alkynyl group, a substituted acyl group, straight or branched alkoxy group, amidyl group, carboxyl group, alkoxyalkyl group, alkylamino group, alkylsulfonyl group, or sulfonic acid group, phenyl group, substituted phenyl group, aryl group, substituted aryl group, or a salt or derivative thereof, and each R₆ and R₇ is independently hydrogen, a hydroxyl group, a substituted C₁-C₆ straight, branched, or cyclic alkyl, alkenyl, or alkynyl group, a substituted acyl group, straight or branched alkoxy group, amidyl group, carboxyl group, alkoxyalkyl group, alkylamino group, alkylsulfonyl group, or sulfonic acid group, phenyl group, substituted phenyl group, aryl group, substituted aryl group, or a salt or derivative thereof. Exemplary oxoammonium compounds include hydroxylamine and N,N-diethylhydroxylamine.

Alkanolamine compounds that may be useful include monoethanolamine, diethanolamine, methyl diethanolamine, triethanolamine, tertiarybutyldiethanolamine, isopropanolamine, diisopropanolamine, 2-amino-1-propanol, 3-amino-1-propanol, isobutanolamine, diglycolamine, 2-amino-2-ethoxy-propanol and 1-hydroxy-2-aminobenzene.

### Solvent

The water miscible solvent advantageously comprises, or alternatively consists essentially of, one or more alkyl glycol ethers, hereafter “glycol ethers.” Glycol ethers are well known and include but are not limited to mono- or dialkyl ethers of polyols such as alkyl ethers of ethylene glycol. Exemplary glycol ether species useful in the compositions include but are not limited to ethylene glycol monomethyl ether (EGME), ethylene glycol monoethyl ether (EGEE), ethylene glycol monopropyl ether (EGPE), ethylene glycol monobutyl ether (EGBE), propylene glycol monomethyl ether (PGME), propylene glycol monoethyl ether (PGEE), propylene glycol monopropyl ether (PGPE), propylene glycol monobutyl ether (PGBE), diethylene glycol monomethyl ether (DGME), diethylene glycol monoethyl ether (DGEE), diethylene glycol monopropyl ether (DGPE), diethylene glycol monobutyl ether (DGBE), dipropylene glycol monomethyl ether (DPGME), dipropylene glycol monoethyl ether (DPGEE), dipropylene glycol monopropyl ether (DPGPE), dipropylene glycol monobutyl ether (DPGBE), triethylene glycol monomethyl ether, triethylene glycol monoethyl ether, triethylene glycol monopropyl ether, triethylene glycol monobutyl ether, tripropylene glycol monomethyl ether, tripropylene glycol mono ethyl ether, tripropylene glycol monopropyl ether, tripropylene glycol monobutyl ether, and mixtures thereof.

Optionally, in another embodiment, the solvent can comprise or consist essentially of glycol ether acetates, e.g., ethylene glycol monomethyl ether acetate, ethylene glycol monoethyl ether acetate, and the like.

Preferred glycol ethers include propylene glycol monoethyl ether (PGEE), propylene glycol monomethyl ether (PGME), diethylene glycol monomethyl ether (DGME), and diethylene glycol monobutyl ether (DGBE). More preferred glycol ethers are PGEE, DGME, and PGME.

Other solvents include but are not limited to sulfoxides such as dimethylsulfoxide, diethylsulfoxide, or methylsulfoxide; sulfones such as dimethyl sulfone, diethyl sulfone, bis(2-hydroxyethyl) sulfone, or tetramethylene sulfone; amides such as N,N-dimethylformamide, N-methylformamide, N,N-dimethylacetamide, N-methylacetamide, or N,N-diethylacetamide; lactams such as N-methyl-2-pyrrolidone, N-ethyl-2-pyrrolidone, N-propyl-2-pyrrolidone, N-hydroxymethyl-2-pyrrolidone, N-hydroxyethyl-2-pyrrolidone, or N-methylpyrrolidinone; imidazolidinones such as 1,3-dimethyl-2-imidazolidinone, 1,3-diethyl-2-imidazolidinone, or 1,3-diisopropyl-2-imidazolidinone; lactones such as gamma.-butyrolactone or delta-valerolactone; and glycols such as ethylene glycol, diethylene glycol, or propylene glycol.

Preferred solvents include sulfoxides, lactams, and glycol ethers.

In one embodiment the organic solvent is present in an amount from 0 to about 95% by weight. In another embodiment the organic solvent is present in an amount from about 50% to about 95% by weight. In another embodiment the organic solvent is preferably present in an amount from about 50% to about 75% by weight.

Preferentially the rinse formulation contains water.

Optionally, the second formulation may also include corrosion inhibitors or chelating agents, as previously described.

Each formulation contacts the substrate for a time period which will be referred to herein as a cleaning cycle. A cleaning cycle may be from about 15 to about 600 seconds, more preferably about 30 to about 300 seconds, more preferably about 60 to about 120 seconds. In certain circumstances, the cleaning cycle may be shortened or extended as deemed appropriate for the particular process, needs, and conditions.

The time between when the first formulation and the second formulation first contact the substrate may differ for each process and may be determined by one of skill in the art, however, it is at least a time sufficient for the first formulation to conduct a cleaning cycle. In one embodiment, the substrate is contacted with the second formulation immediately following the cleaning cycle for the first formulation. In another embodiment, the time between when the first formulation and the second formulation contacts the substrate is at least from about 15 to about 600 seconds. In another embodiment, an extended period of up to an hour elapses between cleaning cycles. The time between cleaning cycles may be extended as deemed appropriate for the process and desired results.

In a preferred embodiment, the rinse formulation is substantially free of water. In another preferred embodiment, the rinse formulation contains from about 2% to about 90% by weight water. In another preferred embodiment, the rinse formulation contains from about 2.5% to about 30% water, more preferably from about 12% to about 15% water.

### Metals Content

Metals content of the compositions is preferably kept low in order to meet metallic contamination targets known in the art, and expressed in for example the Interconnect section of The International Technology Roadmap for Semiconductors: 2003. Concentration of metals such as Al, Ca, Cr, Cu, Fe, Mg, Mn, Ni, Pb, K, Na, and Zn generally are kept less than 10 ppm, preferably less than 5 ppm, for example less than 1 ppm.

### EXAMPLES

TABLE 1
Formulation Examples

| | Basic | | Additional |
|---|---|---|---|
| Formulation | Compound | Solvent | Water |
| EKC804 | 50% MDEA | 25% DPGME | |
| | | 25% NMP | |
| CSX-W22 | 25% THEMAH | 70% DMSO | |
| | 5% HAFB | | |
| CRX05-003 | 25% THEMAH | | 75% |
| CRX05-004 | 25% THEMAH | 75% DMSO | |
| CRX05-005 | 5% HAFB | 95% DMSO | |
| CRX05-006 | 25% THEMAH | 70% DMSO | |
| | 5% DEHA | | |
| CRX05-007 | 22.5% Choline | 70% DMSO | |
| | 5% HAFB | | |
| | 2.5% MDEA | | |
| CRX05-008 | 5% HAFB | 92.5% DMSO | |
| | 2.5% MDEA | | |
| CRX05-009 | 10% MDEA | | 90% |

Choline—Hydroxyethyl trimethyl ammonium hydroxide, 45% solution in water
DIW—Deionized water
DMSO—Dimethyl sulfoxide
HAFB—Hydroxylamine free base, 50% solution in water
MDEA—Methyl diethanolamine
NMP—N-methyl pyrrolidinone
s—Seconds
THEMAH—Tris(hydroxyethyl) methyl ammonium hydroxide, 49% solution in water

### Cleaning Examples

### Cleaning Example 1

Two portions of a wafer were immersed in Formula S2X9 at 50° C. for 300 seconds (“s”). A first portion was rinsed in deionized water (“DIW”), and a second portion was rinsed in isopropyl alcohol (“IPA”); then in DIW. Residues remained on vias and trenches on both portions of the wafer. Another portion of the same wafer was immersed in Formula S2X9 at 30° C. for 90 s, then in CSX-W22 at room temperature for 30 s, and then in DIW. The residue was cleaned and no corrosion noted. Another portion of the same wafer was immersed in S2X9 at 30° C. for 90 s; then in CRX05-009 at room temperature for 30 s; then in DIW. The residue was cleaned and no corrosion noted. This example demonstrates that a process that combines the use of a fluoride formulation with a rinse formulation can remove residues that neither (1) a fluoride formulation alone nor (2) a fluoride formulation in combination with an IPA rinse can remove. This example further demonstrates that excellent cleaning results can be obtained with the two step cleaning process even when the temperature and/or duration of the fluoride formulation are decreased.

### Cleaning Example 2

Nine portions of a wafer were immersed in S2X9 at 30° C. for 90 s. Each of the nine portions was then rinsed in one of EKC804, CSX-W22, CRX05-003, CRX05-004, CRX05-005, CRX05-006, CRX05-007, CRX05-008, and CRX05-009 at room temperature for 30 s; then in DIW. The residue was cleaned and no corrosion noted on each of the nine portions. This example demonstrates that the water component of the rinse formulation may range from 0% as in EKC804 to 90% as in CRX05-009, or even greater than 90%. This example further demonstrates that the solvent component of the rinse formulation may range from 0% as in CRX05-009 to 92.5% as in CRX05-008, or even greater than 92.5%.

### Cleaning Example 3

A wafer was immersed in CSX-W22 at room temperature for 30 s, then in S2X9 at 30° C. for 90 s, then in DIW. The residue was cleaned and no corrosion noted. This example demonstrates that the rinse formulation step may be used prior to the fluoride formulation.

Although the examples used the technique of immersing the wafer portions into a beaker containing the formulations, one skilled in the art recognizes that the short contact times of the examples demonstrates that the cleaning process is well suited for single-wafer processing tools as well as batch processing tools.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

What is claimed is:

1. A process for treating a semiconductor substrate comprising steps of: (1) contacting the substrate with a first formulation; and (2) contacting the substrate with a second formulation comprising (a) a basic compound; (b) 0 to about 90% by weight water; and (c) 0 to about 92.5% by weight organic solvent.

2. The process of claim 1 in which the basic compound is present in an amount of from about 5 percent by weight to about 50 percent by weight.

3. The process of claim 1 in which the basic compound is selected from the group consisting of organic ammonium compounds; oxoammonium compounds; and alkanolamines.

4. The process of claim 1 in which the organic solvent is selected from the group consisting of sulfoxides, lactams, and glycol ethers.

5. The process of claim 2, wherein the organic solvent is in the second formulation.

6. The process of claim 3, wherein the organic solvent is in the second formulation.

7. The process of claim 5, wherein the organic solvent is selected from the group consisting of sulfoxides, lactams, and glycol ethers.

8. The process of claim 6, wherein the organic solvent is selected from the group consisting of sulfoxides, lactams, and glycol ethers.

9. The process of claim 2, wherein water is in the second formulation.

10. The process of claim 3, wherein water is in the second formulation.

11. A process for treating a semiconductor substrate comprising steps of: (1) contacting the substrate with a first formulation; and (2) contacting the substrate with a second formulation comprising (a) about 5% to about 50% by weight of a basic compound; (b) 0 to about 90% by weight water; and (c) 0 to about 92.5% by weight organic solvent.

12. The process of claim 11, wherein the basic compound (a) is selected from the group consisting of organic ammonium compounds; oxoammonium compounds; water (b) is present in the second formulation; and alkanolamines; and the organic solvent (c) is selected from the group consisting of sulfoxides, lactams, and glycol ethers.

13. The process of claim 1 in which the semiconductor substrate comprises a titanium nitride layer hard mask.

14. The process of claim 11 in which the semiconductor substrate comprises a titanium nitride layer hard mask.

15. The process of claim 13, wherein said hard mask is over a low-k dielectric layer.

16. The process of claim 14, wherein said hard mask is over a low-k dielectric layer.

17. The process of claim 1 wherein the first formulation comprises a fluoride-providing component.

18. The process of claim 11 wherein the first formulation comprises a fluoride-providing component.

19. A process for treating a semiconductor substrate comprising steps of: (1) contacting the substrate with a first formulation comprising (a) about 5% to about 50% by weight of a basic compound; (b) 0 to about 90% by weight water; and (c) 0 to about 92.5% by weight organic solvent; and subsequently (2) contacting the substrate with a formulation comprising a fluoride-providing component.

20. The process of claim 19 wherein the substrate is rinsed with water between step (1) and step (2).
